(19) United States
(12) Patent Application Publication
(10) Pub. No.: US 2025/0075940 A1
(43) Pub. Date: Mar. 6, 2025

(54) WATER HEATER APPLIANCE AND HEAT TRANSFER ASSEMBLY

(71) Applicant: Haier US Appliance Solutions, Inc., Wilmington, DE (US)

(72) Inventors: Spencer Paire, Louisville, KY (US); Craig Tsai, Louisville, KY (US)

(21) Appl. No.: 18/461,185

(22) Filed: Sep. 5, 2023

(51) Int. Cl. F24H 4/04; F24D 17/02; H05K 7/20

(52) U.S. Cl. CPC F24H 4/04; F24D 17/02; H05K 7/20336

(57) ABSTRACT

A water heater appliance or heat transfer assembly may include a refrigeration system, an electronics board, and a heat pipe. The refrigeration system may include a sealed refrigerant loop. The electronics board may be attached to a housing. The heat pipe may extend between a conductive interface or electronics board and the sealed refrigerant loop to convey waste heat from the electronics board to the sealed refrigerant loop.

### FIELD OF THE DISCLOSURE

The present subject matter relates generally to heating transfer assemblies, such as to cool electronics, and more particularly to heat transfer assemblies for water heater appliances.

### BACKGROUND OF THE DISCLOSURE

Water heater appliances are often used for storing and supplying hot water to residential and commercial properties. Energy efficiency is a common concern in such appliances, as significant energy may be required to heat or maintain water for immediate use by an owner or user of the appliance. Recently, heat pump water heaters have gaining broader acceptance as a more economic and ecologically-friendly alternative to electric water heaters. Heat pump water heaters include a sealed system for heating water to a set temperature. The sealed system generally includes a condenser configured in a heat exchange relationship with a water storage tank within the water heater appliance and an evaporator. A microcontroller or processor may be provided, such as to control or direct operation of the sealed system- or of the water heater appliance generally.

As noted above, energy efficiency is a common concern or issue for water heater appliances. Although a heat pump having a sealed refrigeration system can improve the efficiency in heating or maintaining heated water, challenges still exist. For instance, efficiency or efficacy of the system can often be limited by the ambient environment in which the water heater appliance is installed. Such environments are often untreated (e.g., within a garage or attic) and, thus, typically subjected to much lower and higher temperatures than other household appliances. Additionally or alternatively, concerns may arise with efficiently or effectively operating a microprocessor in the relatively harsh environment in which a water heater appliance is installed.

As a result, further improvements to water heater appliances or heat transfer assemblies would be useful. In particular, it may be advantageous to provide a water heater appliance or heat transfer assembly for efficiently or effectively operating, even in relatively extreme or untreated environments.

### BRIEF DESCRIPTION OF THE DISCLOSURE

Aspects and advantages of the invention will be set forth in part in the following description, or may be obvious from the description, or may be learned through practice of the invention.

In one exemplary aspect of the present disclosure, a water heater appliance is provided. The water heater appliance may include a housing, a tank, a refrigeration system, an electronics board, a conductive interface, and a heat pipe. The tank may be attached to the housing, the tank defining an interior volume. The refrigeration system may include a sealed refrigerant loop in thermal communication with the tank to heat the interior volume. The electronics board may be attached to the housing apart from the tank. The conductive interface may be connected to the electronics board and spaced apart from the refrigerant loop. The heat pipe may extend between the conductive interface and the sealed refrigerant loop to convey waste heat from the electronics board to the sealed refrigerant loop.

In another exemplary aspect of the present disclosure, a heat transfer assembly is provided. The heat transfer assembly may include a refrigeration system, an electronics board, a conductive interface, and a heat pipe. The refrigeration system may include a sealed refrigerant loop. The electronics board may be attached to the housing apart from the tank. The conductive interface may be connected to the electronics board and spaced apart from the refrigerant loop. The heat pipe may extend from a first end proximal to the conductive interface to a second end proximal to the sealed refrigerant loop and above the first end to convey waste heat from the electronics board to the sealed refrigerant loop. The conductive interface may define an internal channel encapsulating the heat pipe. The outer surface of the heat pipe may be in conductive thermal contact with an inner surface of the internal channel of the conductive interface.

In yet another exemplary aspect of the present disclosure, a water heater appliance is provided. The water heater appliance may include a housing, a tank, a refrigeration system, an electronics board, and a heat pipe. The tank may be attached to the housing, the tank defining an interior volume. The refrigeration system may include a sealed refrigerant loop in thermal communication with the tank to heat the interior volume. The electronics board may be attached to the housing apart from the tank. The conductive interface may be connected to the electronics board and spaced apart from the refrigerant loop. The heat pipe may extend between the electronics board and the sealed refrigerant loop to convey waste heat from the electronics board to the sealed refrigerant loop.

These and other features, aspects and advantages of the present invention will become better understood with reference to the following description and appended claims. The accompanying drawings, which are incorporated in and constitute a part of this specification, illustrate embodiments of the invention and, together with the description, serve to explain the principles of the invention.

### BRIEF DESCRIPTION OF THE DRAWINGS

A full and enabling disclosure of the present invention, including the best mode thereof, directed to one of ordinary skill in the art, is set forth in the specification, which makes reference to the appended figures.

FIG. 1 provides a perspective view of a water heater appliance according to an exemplary embodiment of the present subject matter.

FIG. 2 provides a schematic view of certain components of the exemplary water heater appliance of FIG. 1.

FIG. 3 provides a partial perspective view of certain components of the exemplary water heater appliance of FIG. 1.

FIG. 4 provides a partial perspective view of certain heater-transfer components of a water heater appliance according to an exemplary embodiment of the present subject matter.

FIG. 5 provides a perspective view of certain heat-transfer components, in isolation, of the exemplary water heater appliance of FIG. 1.

FIG. 6 provides a perspective view of the exemplary heat-transfer components of FIG. 5.

FIG. 7 provides another perspective view of the exemplary heat-transfer components of FIG. 5.

FIG. 8 a perspective view of various exemplary heat-transfer components of FIG. 5.

FIG. 9 another perspective view of various exemplary heat-transfer components of FIG. 5.

FIG. 10 provides a partial perspective view of certain heater-transfer components of the exemplary water heater appliance of FIG. 1.

FIG. 11 provides a perspective view of a pipe clip for attaching a heat pipe to a sealed system according to an exemplary embodiment of the present subject matter.

FIG. 12 provides another perspective view of a pipe clip for attaching a heat pipe to a sealed system according to an exemplary embodiment of the present subject matter.

Repeat use of reference characters in the present specification and drawings is intended to represent the same or analogous features or elements of the present invention.

### DETAILED DESCRIPTION

Reference now will be made in detail to embodiments of the invention, one or more examples of which are illustrated in the drawings. Each example is provided by way of explanation of the invention, not limitation of the invention. In fact, it will be apparent to those skilled in the art that various modifications and variations can be made in the present invention without departing from the scope of the invention. For instance, features illustrated or described as part of one embodiment can be used with another embodiment to yield a still further embodiment. Thus, it is intended that the present invention covers such modifications and variations as come within the scope of the appended claims and their equivalents.

As used herein, the terms “first,” “second,” and “third” may be used interchangeably to distinguish one component from another and are not intended to signify location or importance of the individual components. The terms “includes” and “including” are intended to be inclusive in a manner similar to the term “comprising.” Similarly, the term “or” is generally intended to be inclusive (i.e., “A or B” is intended to mean “A or B or both”). In addition, here and throughout the specification and claims, range limitations may be combined or interchanged. Such ranges are identified and include all the sub-ranges contained therein unless context or language indicates otherwise. For example, all ranges disclosed herein are inclusive of the endpoints, and the endpoints are independently combinable with each other. The singular forms “a,” “an,” and “the” include plural references unless the context clearly dictates otherwise.

Approximating language, as used herein throughout the specification and claims, may be applied to modify any quantitative representation that could permissibly vary without resulting in a change in the basic function to which it is related. Accordingly, a value modified by a term or terms, such as “generally,” “about,” “approximately,” and “substantially,” are not to be limited to the precise value specified. In at least some instances, the approximating language may correspond to the precision of an instrument for measuring the value, or the precision of the methods or machines for constructing or manufacturing the components or systems. For example, the approximating language may refer to being within a 10 percent margin (i.e., including values within ten percent greater or less than the stated value). In this regard, for example, when used in the context of an angle or direction, such terms include within ten degrees greater or less than the stated angle or direction (e.g., “generally vertical” includes forming an angle of up to ten degrees in any direction, such as, clockwise or counterclockwise, with the vertical direction V).

The word “exemplary” is used herein to mean “serving as an example, instance, or illustration.” In addition, references to “an embodiment” or “one embodiment” does not necessarily refer to the same embodiment, although it may. Any implementation described herein as “exemplary” or “an embodiment” is not necessarily to be construed as preferred or advantageous over other implementations. Moreover, each example is provided by way of explanation of the invention, not limitation of the invention. In fact, it will be apparent to those skilled in the art that various modifications and variations can be made in the present invention without departing from the scope of the invention. For instance, features illustrated or described as part of one embodiment can be used with another embodiment to yield a still further embodiment. Thus, it is intended that the present invention covers such modifications and variations as come within the scope of the appended claims and their equivalents.

The terms “coupled,” “fixed,” “attached to,” and the like refer to both direct coupling, fixing, or attaching, as well as indirect coupling, fixing, or attaching through one or more intermediate components or features, unless otherwise specified herein.

Except as explicitly indicated otherwise, recitation of a singular processing element (e.g., “a controller,” “a processor,” “a microprocessor,” etc.) is understood to include more than one processing element. In other words, “a processing element” is generally understood as “one or more processing element.” Furthermore, barring a specific statement to the contrary, any steps or functions recited as being performed by “the processing element” or “said processing element” are generally understood to be capable of being performed by “any one of the one or more processing elements.” Thus, a first step or function performed by “the processing element” may be performed by “any one of the one or more processing elements,” and a second step or function performed by “the processing element” may be performed by “any one of the one or more processing elements and not necessarily by the same one of the one or more processing elements by which the first step or function is performed.” Moreover, it is understood that recitation of “the processing element” or “said processing element” performing a plurality of steps or functions does not require that at least one discrete processing element be capable of performing each one of the plurality of steps or functions.

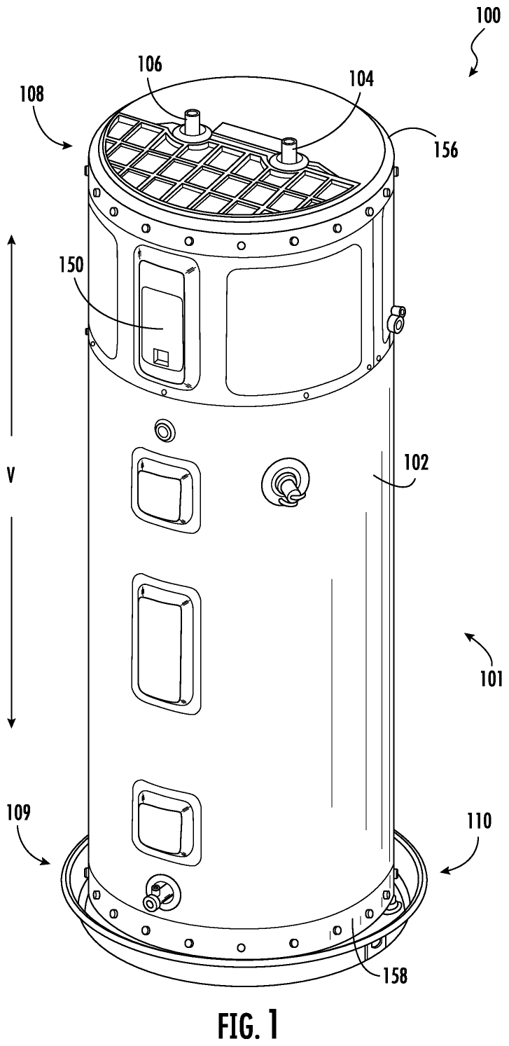

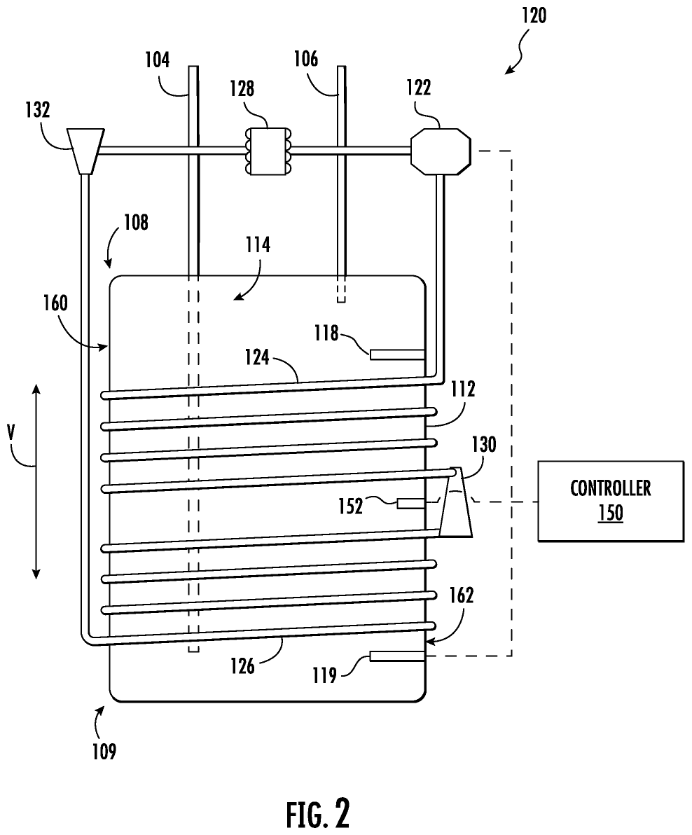

FIG. 1 provides a perspective view of a water heater appliance 100 according to an exemplary embodiment of the present subject matter. Generally, water heater appliance 100 has a housing 101 that includes an outer shell or casing 102. Casing 102 generally attaches to (e.g., surrounds) a tank 112 (FIG. 2). In some embodiments, tank 112 is disposed within casing 102. Housing 101 or casing 102 may be formed from a variety of components. As illustrated, casing 102 may include a wrapper 154 and one or more covers, such as a top cover 156 and a bottom cover 158 as illustrated. Covers 156, 158 may be fastened or coupled to wrapper 154 to form casing 102.

Turning briefly to FIG. 2, FIG. 2 provides a schematic view of certain components of water heater appliance 100. Further attached to or positioned within casing 102 is a heating assembly for heating water within tank 112. The heating assembly may include an upper or lower heating element 118, 119. Additionally or alternatively, the heating assembly may include a sealed system 120 (i.e., refrigeration system including a sealed refrigeration loop). Upper and lower heating elements 118, 119 can be any suitable heating elements. For example, upper heating element 118 or lower heating element 119 may be an electric resistance element, a microwave element, an induction element, or any other suitable heating element or combination thereof. Lower heating element 119 may also be a gas burner. As will be understood by those skilled in the art and as used herein, the term “water” includes purified water and solutions or mixtures containing water and, for example, elements (such as calcium, chlorine, and fluorine), salts, bacteria, nitrates, organics, and other chemical compounds or substances.

Returning generally to FIGS. 1 and 2, water heater appliance 100 may include an inlet or cold water conduit 104 and an outlet or hot water conduit 106. Both conduits 104, 106 may be in fluid communication with a chamber or interior volume 114 (FIG. 2) defined by tank 112. As an example, cold water from a water source (e.g., a municipal water supply or a well) can enter water heater appliance 100 through cold water conduit 104. From cold water conduit 104, such cold water can enter interior volume 114 of tank 112 wherein it is heated with heating elements 118, 119 or sealed system 120 to generate heated water. Such heated water can exit water heater appliance 100 at hot water conduit 106 and, for example, be supplied to a bath, shower, sink, or any other suitable feature.

In exemplary embodiments, water heater appliance 100 extends longitudinally between a top portion 108 and a bottom portion 109 along a vertical direction V. Thus, water heater appliance 100 is generally vertically oriented. Water heater appliance 100 can be leveled (e.g., such that casing 102 is plumb in the vertical direction V) in order to facilitate proper operation of water heater appliance 100. A drain pan 110 is positioned at bottom portion 109 of water heater appliance 100 such that water heater appliance 100 sits on drain pan 110. Drain pan 110 sits beneath water heater appliance 100 along the vertical direction V (e.g., to collect water that leaks from water heater appliance 100 or water that condenses on an evaporator 128 of water heater appliance 100). It should be understood that water heater appliance 100 is provided by way of example only and that the present subject matter may be used with any suitable water heater appliance, including for example a heat pump water heater appliance.

As may be seen in FIG. 2, water heater appliance 100 may include sealed system 120 for heating water within interior volume 114 of tank 112. Sealed system 120 generally operates in a heat pump cycle. Thus, water heater appliance 100 is commonly referred to as a “heat pump water heater appliance.” Water heater appliance 100 may additionally include one or more auxiliary heating elements, such as upper heating element 118 or lower heating element 119.

Sealed system 120 may include a compressor 122, one or more condensers (e.g., a first condenser 124 and a second condenser 126), and an evaporator 128. Compressor 122 or evaporator 128 of sealed system 120 may be disposed within casing 102 at top portion 108 of water heater appliance 100. As is generally understood, various conduits may be utilized to flow refrigerant between the various components of sealed system 120. Thus, for example, evaporator 128 may be between and in fluid communication with second condenser 126 and compressor 122. During operation of sealed system 120, refrigerant may flow from evaporator 128 through compressor 122. For example, refrigerant may exit evaporator 128 as a fluid in the form of a superheated vapor or high quality vapor mixture. Upon exiting evaporator 128, the refrigerant may enter compressor 122. Compressor 122 may be operable to compress the refrigerant. Accordingly, the pressure and temperature of the refrigerant may be increased in compressor 122 such that the refrigerant becomes a superheated vapor.

Each condenser 124, 126 may be assembled in a heat exchange relationship with tank 112 in order to heat water within interior volume 114 of tank 112 during operation of sealed system 120. First condenser 124 may be positioned downstream of and in fluid communication with compressor 122, and may be operable to heat the water within interior volume 114 using energy from the refrigerant. For example, the superheated vapor from compressor 122 may enter first condenser 124 wherein it transfers energy to the water within tank 112 and condenses into a saturated liquid or liquid vapor mixture. Second condenser 126 may be positioned downstream of and in fluid communication with first condenser 124, and may additionally be operable to heat the water within interior volume 114 using energy from the refrigerant, such as by further condensing the refrigerant.

Sealed system 120 may also include a first throttling device 130 between first condenser 124 and second condenser 126, or a second throttling device 132 between second condenser 126 and evaporator 128. Refrigerant, which may be in the form saturated liquid vapor mixture, may exit first condenser 124 and travel through first throttling device 130 before flowing through second condenser 126. First throttling device 130 may generally expand the refrigerant, lowering the pressure and temperature thereof. The refrigerant may then be flowed through second condenser 126. Similarly, refrigerant, which may be in the form of high quality/saturated liquid vapor mixture, may exit second condenser 126 and travel through second throttling device 132 before flowing through evaporator 128. Second throttling device 132 may generally expand the refrigerant, lowering the pressure and temperature thereof. The refrigerant may then be flowed through evaporator 128.

First or second throttling device 130, 132 may be any suitable component(s)s for generally expanding the refrigerant. For example, in some exemplary embodiments, first and second throttling device 130, 132 may be a Joule-Thomson expansion valve, also known as a “J-T valve.” In other exemplary embodiments, first and second throttling device 130, 132 may be an ejector. In still other exemplary embodiments, a capillary tube, fixed orifice, or other suitable apparatus may be utilized as first and second throttling device 130, 132.

Water heater appliance 100 may additionally include a temperature sensor 152. Temperature sensor 152 may be configured for measuring a temperature of water within interior volume 114 of tank 112. Temperature sensor 152 can be positioned at any suitable location within water heater appliance 100. For example, temperature sensor 152 may be positioned within interior volume 114 of tank 112 or may be mounted to tank 112 outside of interior volume 114 of tank 112. Temperature sensor 152 may further be positioned within upper portion 160 or lower portion 162. When mounted to tank 112 outside of interior volume 114 of tank 112, temperature sensor 152 can be configured for indirectly measuring the temperature of water within interior volume 114 of tank 112. For example, temperature sensor 152 can measure the temperature of tank 112 and correlate the temperature of tank 112 to the temperature of water within interior volume 114 of tank 112. Temperature sensor 152 may be any suitable temperature sensor. For example, temperature sensor 152 may be a thermocouple or a thermistor.

In some embodiment, water heater appliance 100 further includes a controller 150 that regulates operation of water heater appliance 100. Controller 150 may be, for example, in operative communication with sealed system 120 (such as compressor 122, or other components thereof), auxiliary heating elements, or temperature sensor 152. Thus, controller 150 can selectively activate system 120 or auxiliary heating elements in order to heat water within interior volume 114 of tank 112.

In certain embodiments, controller 150 includes memory and one or more processing devices such as microprocessors, CPUs or the like, such as general or special purpose microprocessors operable to execute programming instructions or micro-control code associated with operation of water heater appliance 100. The memory can represent random access memory such as DRAM, or read only memory such as ROM or FLASH. During use, the processor executes programming instructions stored in the memory. The memory can be a separate component from the processor or can be included onboard within the processor. Alternatively, controller 150 may be constructed without using a microprocessor (e.g., using a combination of discrete analog or digital logic circuitry; such as switches, amplifiers, integrators, comparators, flip-flops, AND gates, and the like) to perform control functionality instead of relying upon software.

Generally, controller 150 may be mounted at any suitable location on or within housing 101. In particular, at least one electronics board 210 (e.g., such as a control board, circuit, MOSFET, or inverter board of controller 150) may be housed or mounted within top cover 156, as will be described in greater detail below.

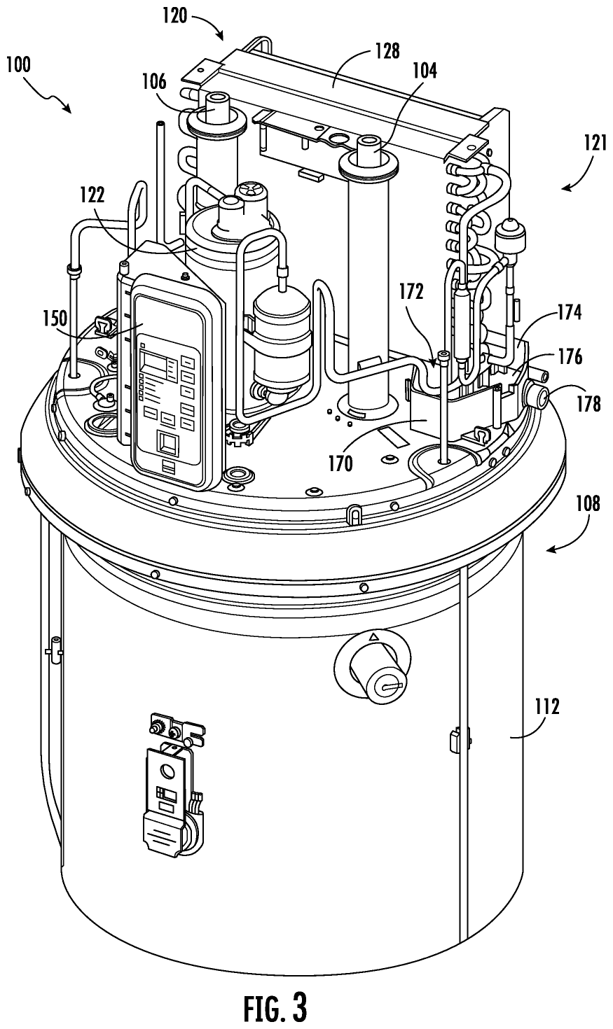

FIG. 3 provides a partial perspective view of certain components of water heater appliance 100. As may be seen in FIG. 3, water heater appliance 100 may include a drain pan 170. For instance, drain pan 170 may be positioned below evaporator 128 of sealed system 120. In particular, drain pan 170 may be positioned for receiving liquid runoff from evaporator 128 of sealed system 120. Thus, during a defrost cycle of sealed system 120, frost buildup on evaporator 128 may melt, and liquid runoff may flow to and collect within drain pan 170. Drain pan 170 may be positioned within casing 102. In some embodiments, both evaporator 128 and drain pan 170 are be disposed within the casing 102 (e.g., at or adjacent top portion 108 of casing 102, such as within the top cover 156-FIG. 1).

Drain pan 170 may define a collection volume 172 for receiving and collecting liquid runoff from evaporator 128. Collection volume 172 may be positioned directly below at least a portion of evaporator 128 or above (e.g., directly above) tank 112. Drain pan 170 may include a side wall 174 and a bottom wall 176 that assist with defining collection volume 172. In some embodiments, side wall 174 is mounted to and extends about bottom wall 176. Side wall 174 may also extend upwardly from bottom wall 176. Side wall 174 or bottom wall 176 may include a drain line coupling 178. Drain line coupling 178 is configured for engaging a drain line (not shown), such as a pipe or hose. The drain line may receive liquid from collection volume 172 of drain pan 170 and direct the liquid out of and away from drain pan 170. Drain line coupling 178 may be threaded in order to assist with mounting the drain line to drain line coupling 178. As another example, the drain line may be adhered or fastened to drain line coupling 178.

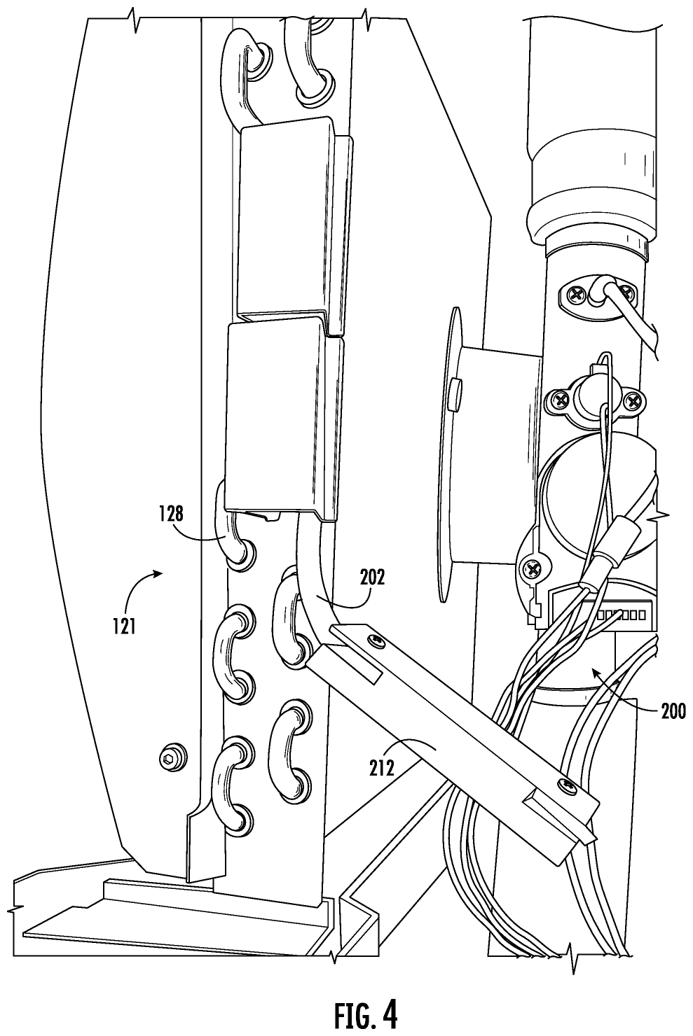

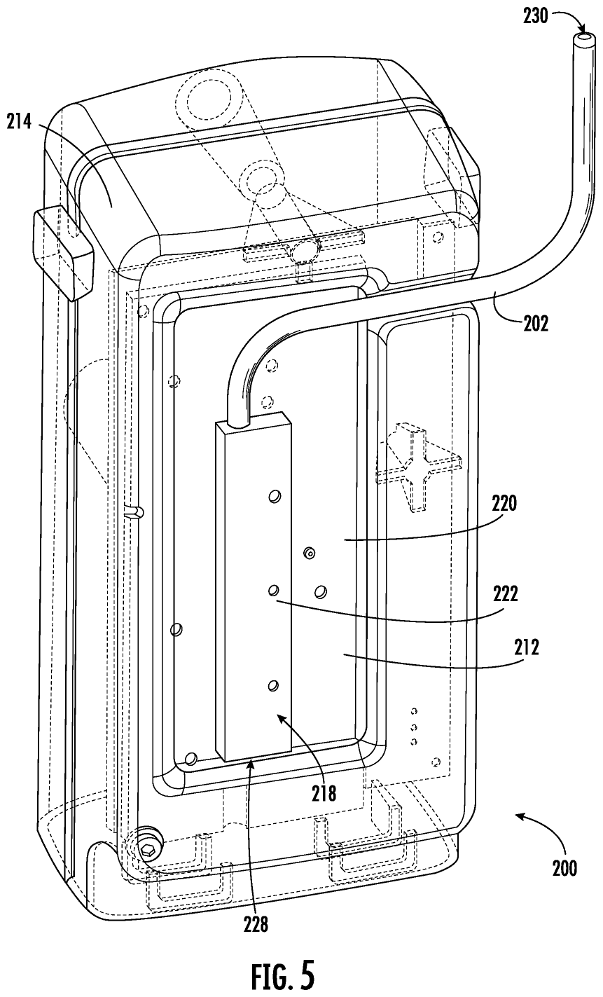

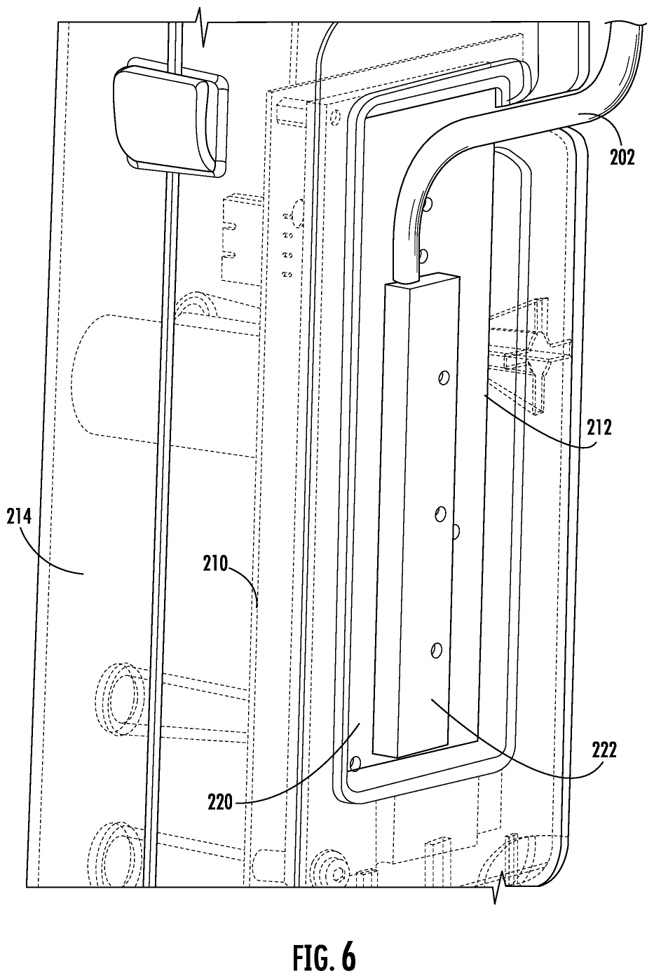

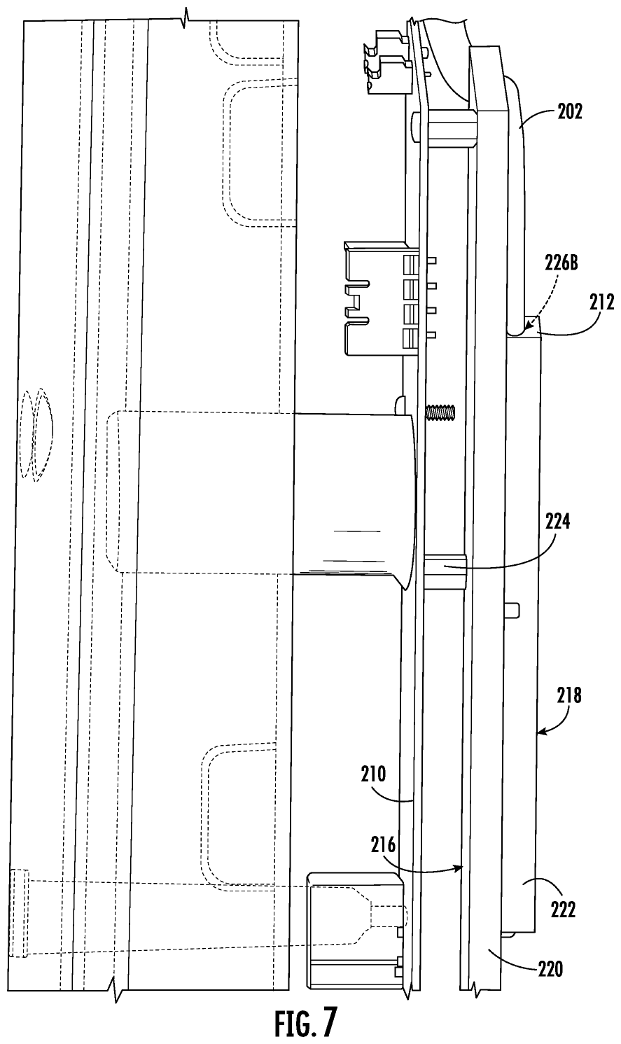

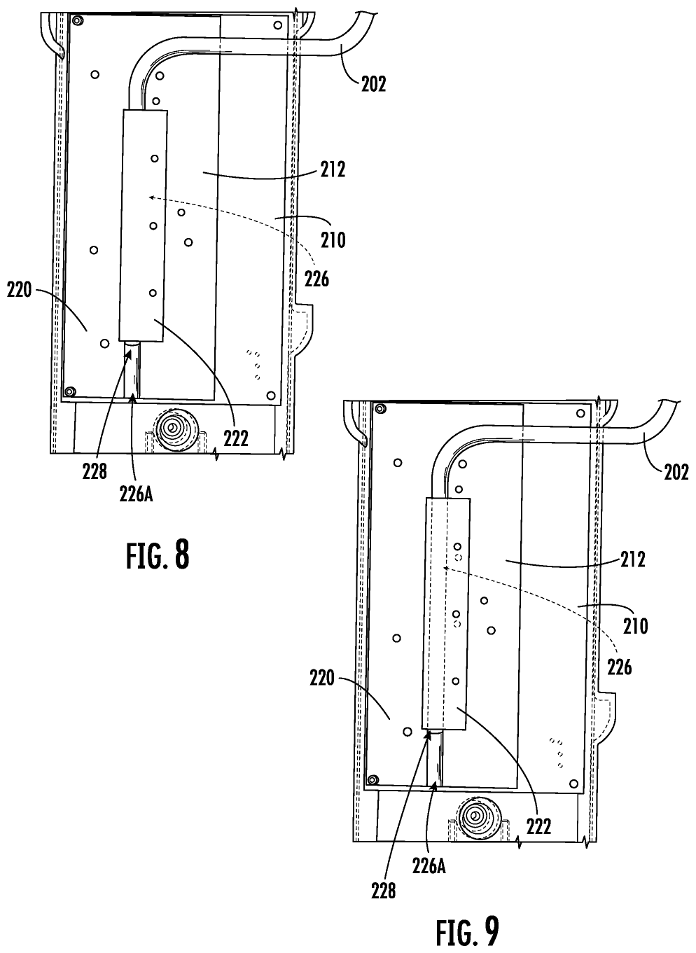

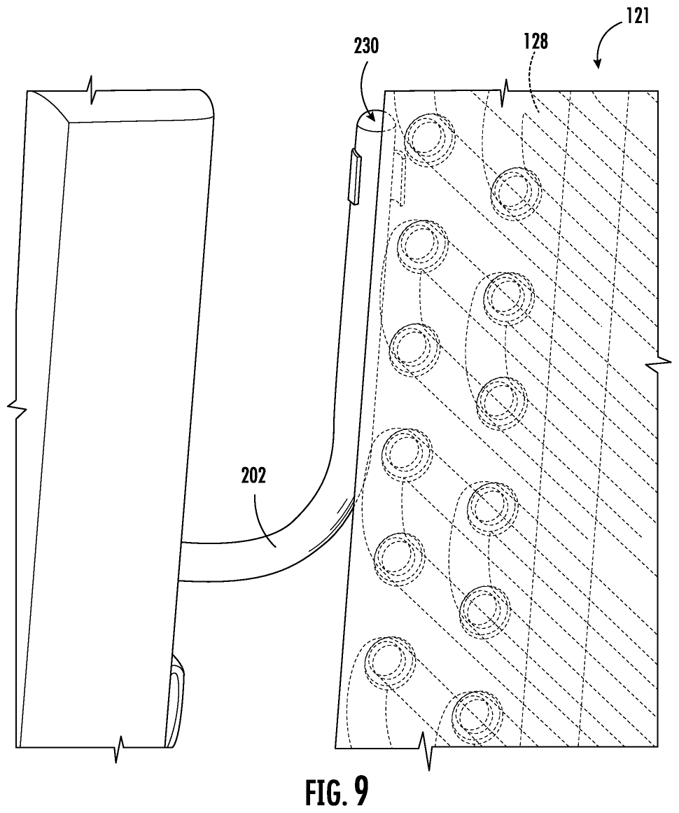

Turning now to FIGS. 4 through 10, various views are provided of heat-transfer components for a heat transfer assembly 200 of water heater appliance 100. Generally, the heat transfer assembly 200 includes an electronics board 210, conductive interface (e.g., pipe-mounting bracket) 212, and heat pipe 202 for transferring heat from the electronics board 210 to the refrigerant loop 121 of the sealed system 120.

As noted above, electronics board 210 may be included as or as part of controller 150. Moreover, electronics board 210 may include a printed circuit board (PCB) on which one or more electronics or circuits components are mounted, as is understood. When assembled, electronics board 210 may be attached to or housed within casing 102. In some embodiments, electronics board 210 is provided apart from the tank 112. For instance, electronics board 210 may be spaced apart from tank 112 (e.g., such that electronics board 210 is not supported directly on tank 112). Additionally or alternatively, electronics board 210 may be supported or held within an electronics compartment 214. Optionally, electronics compartment 214 may be mounted on or formed as part of top cover 156. Additionally or alternatively, electronics compartment 214 may be above or vertically spaced apart from drip pan 170. In some embodiments, electronics board 210 is disposed above the tank 112 (e.g., directly above). Thus, electronics board 210 may be positioned apart from tank 112 at a relative height that is greater than tank 112 (e.g., while being vertically aligned with at least a portion of tank 112).

Connected to the electronics board 210 may be a conductive interface 212, such as a pipe-mounting bracket (e.g., pictured). Generally, conductive interface 212 may be formed from one or more conductive materials (e.g., metals, such as copper or aluminum, including alloys thereof). As shown, electronics board 210 may be spaced apart from tank or refrigerant loop 121 (e.g., such that electronics board 210 does not contact the same). In some embodiments, conductive interface 212 is mounted on or embedded within electronics compartment 214 (e.g., via one or more mechanical fasteners, adhesives, welds, etc.). At least a portion or surface (e.g., interior surface 216) may be exposed to an interior portion of electronics compartment 214. For instance, an interior surface 216 of conductive interface 212 may face electronics board 210 within electronics compartment 214 while an exterior surface 218 may be directed away from electronics compartment 214 or electronics board 210 (e.g., within a surrounding portion of top cover 156 inside casing 102). In optional embodiments, conductive interface 212 may be formed from or include a plurality of discrete plates 220, 222 (e.g., rigidly attached together), as will be described in greater detail below. Thus, at least a portion of interior surface 216 may be defined by one plate (e.g., first plate 220), while at least a portion of exterior surface 218 is defined by another plate (e.g., second plate 222).

When assembled, conductive interface 212 may be in thermal communication (e.g., conductive thermal communication) with electronics board 210 (e.g., at the interior surface 216). Electronics board 210 may be held directly on conductive interface 212 or, alternatively, connected to the same via one or more conductive elements. Optionally, a plurality of standoffs 224 may hold the electronics board 210 to the metal heat sink conductive interface 212. Additionally or alternatively, electronics board 210 may be horizontally aligned (e.g., at a common or overlapping vertical height) with conductive interface 212, notably facilitating a compact construction.

Along with connecting to electronics board 210, conductive interface 212 may in thermal communication (e.g., conductive thermal communication) with heat pipe 202. For instance, conductive interface 212 may be joined to heat pipe 202 (e.g., in support thereof). In some such embodiments, at least a portion or segment of heat pipe 202 is held on or within conductive interface 212. As an example, conductive interface 212 may define an internal channel 226 to receive at least a portion of heat pipe 202. In particular, internal channel 226 may encapsulate heat pipe 202 (i.e., a portion or segment thereof). Moreover, an outer surface of the heat pipe 202 may be in conductive thermal contact with an inner surface of the internal channel 226 of the conductive interface 212 (e.g., directly, including with the aid of a thermal paste or grease). The heat pipe 202 may be surrounded by internal channel 226 along a sub-portion of the entire length of heat pipe 202 (e.g., measured between a first end 228 and a second end 230). As shown, the internal channel 226 may be formed by the separate plates 220, 222, which may have matching grooves 226A, 226B that define internal channel 226.

Generally, the heat pipe 202 is provided as a thermally-conductive body formed from one or more suitable materials (e.g., copper or aluminum, including alloys thereof). Within heat pipe 202 a sealed void may be defined (e.g., to house a fluid refrigerant, such as water or ethylene glycol). As noted above, heat pipe 202 may extend along a length from a first end 228 to a second end 230 (e.g., within the casing 102 or above the tank 112). When assembled, the first end 228 may be positioned proximal to conductive interface 212 (e.g., thereon or within internal channel 226). By contrast, the second end 230 may be positioned apart from conductive interface 212. Specifically, the second end 230 may be proximal to a portion of the refrigerant loop 121 (i.e., distal to the conductive interface 212). In some embodiments, the second end 230 is further positioned above the first end 228. Thus, the heat pipe 202 may generally extend upward along its length toward the refrigerant loop 121, and notably draw heat from first end 228. Additionally or alternatively, the second end 230 may be horizontally offset from the first end 228. Moreover, the refrigerant loop 121 may be horizontally offset from the electronics board 210 or conductive interface 212. Notably, the accumulation or flow of liquids (e.g., condensed water from the air) on the electronics board 210 or within electronics compartment 214 may be prevented.

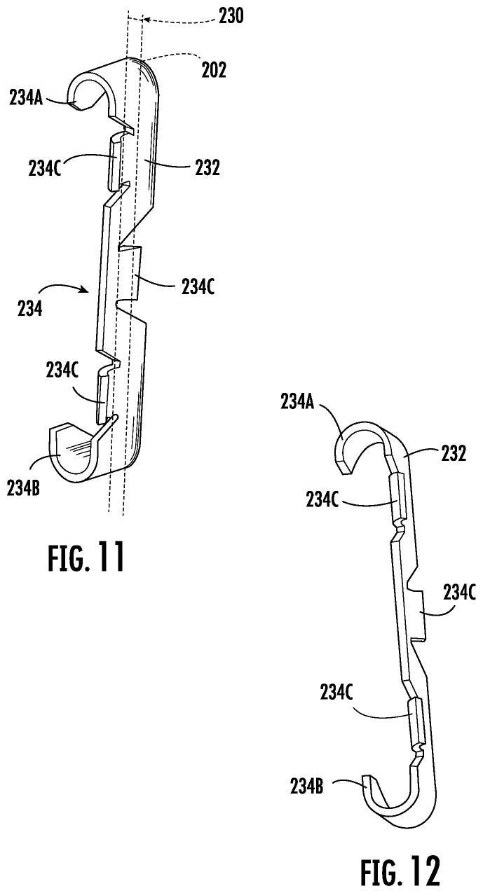

As noted above, the second end 230 of the heat pipe 202 may be positioned proximate to the refrigerant loop 121. In particular, the second end 230 may be proximal to the evaporator 128. When assembled, the heat pipe 202 may, in turn, be in thermal communication (e.g., conductive thermal communication) with the evaporator 128. In some embodiments, the heat pipe 202 is connected or secured to the refrigerant loop 121. For instance, the heat pipe 202 may be clipped to the refrigerant loop 121 (e.g., at the evaporator 128), as shown. Turning especially to FIG. 10 through 12, a loop clip 232 may be provided to clip or hold the heat pipe 202 (e.g., at the second end 230) to the evaporator 128. In certain embodiments, the loop clip 232 includes plurality of conductor wings 234. As shown, such conductor wings 234 may extend extending horizontally between the heat pipe 202 and the evaporator 128. In the illustrated embodiments, a pair of upper and lower wings 234A, 234B mount to separate coils or turns of the evaporator 128 while two or more lateral wings 234C mount to and horizontally retain the heat pipe 202.

Advantageously, the above-described embodiments may facilitate efficient or effective heat transfer from the electronics board 210 to the evaporator 128, thereby improving performance of the sealed system 120 or components on the electronics board 210.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal languages of the claims.

What is claimed is:

1. A water heater appliance comprising:
a housing;
a tank attached to the housing, the tank defining an interior volume;
a refrigeration system comprising a sealed refrigerant loop in thermal communication with the tank to heat the interior volume;
an electronics board attached to the housing apart from the tank;
a conductive interface connected to the electronics board and spaced apart from the refrigerant loop; and
a heat pipe extending between the conductive interface and the sealed refrigerant loop to convey waste heat from the electronics board to the sealed refrigerant loop.

2. The water heater appliance of claim 1, wherein the conductive interface defines an internal channel encapsulating the heat pipe, and wherein an outer surface of the heat pipe is in conductive thermal contact with an inner surface of the internal channel of the conductive interface.

3. The water heater appliance of claim 2, wherein the conductive interface comprises a plurality of plates rigidly attached together, and wherein the plurality of plates define matching grooves defining the internal channel of the conductive interface.

4. The water heater appliance of claim 1, wherein the heat pipe is clipped to the sealed refrigerant loop.

5. The water heater appliance of claim 1, wherein the heat pipe extends from a first end proximal to the conductive interface to a second end proximal to the sealed refrigerant loop and above the first end.

6. The water heater appliance of claim 5, wherein the sealed refrigerant loop comprises an evaporator, and wherein the second end of the heat pipe is proximal to the evaporator in conductive thermal communication therewith.

7. The water heater appliance of claim 6, further comprising a plurality of conductor wings extending horizontally between the heat pipe and the evaporator.

8. The water heater appliance of claim 7, wherein the first end is horizontally offset from the second end.

9. The water heater appliance of claim 7, wherein the plurality of conductor wings horizontally bound a portion of the evaporator and restrain relative movement between the heat pipe and the evaporator.

10. The water heater appliance of claim 1, wherein the electronics board and the heat pipe are disposed directly above the tank.

11. A heat-transfer assembly comprising:
a refrigeration system comprising a sealed refrigerant loop;
an electronics board attached to the housing apart from the tank;
a conductive interface connected to the electronics board and spaced apart from the refrigerant loop; and
a heat pipe extending from a first end proximal to the conductive interface to a second end proximal to the sealed refrigerant loop and above the first end to convey waste heat from the electronics board to the sealed refrigerant loop,
wherein the conductive interface defines an internal channel encapsulating the heat pipe, and
wherein an outer surface of the heat pipe is in conductive thermal contact with an inner surface of the internal channel of the conductive interface.

12. The heat-transfer assembly of claim 11, wherein the conductive interface comprises a plurality of plates rigidly attached together, and wherein the plurality of plates define matching grooves defining the internal channel of the conductive interface.

13. The heat-transfer assembly of claim 11, wherein the heat pipe is clipped to the sealed refrigerant loop.

14. The heat-transfer assembly of claim 11, wherein the heat pipe extends from a first end proximal to the conductive interface to a second end proximal to the sealed refrigerant loop and above the first end.

15. The heat-transfer assembly of claim 14, wherein the sealed refrigerant loop comprises an evaporator, and wherein the second end of the heat pipe is proximal to the evaporator in conductive thermal communication therewith.

16. The heat-transfer assembly of claim 15, further comprising a plurality of conductor wings extending horizontally between the heat pipe and the evaporator.

17. The heat-transfer assembly of claim 16, wherein the first end is horizontally offset from the second end.

18. The heat-transfer assembly of claim 17, wherein the plurality of conductor wings horizontally bound a portion of the evaporator and restrain relative movement between the heat pipe and the evaporator.

19. A water heater appliance comprising:
a housing;
a tank attached to the housing, the tank defining an interior volume;
a refrigeration system comprising a sealed refrigerant loop in thermal communication with the tank to heat the interior volume;
an electronics board attached to the housing apart from the tank; and
a heat pipe extending between the electronics board and the sealed refrigerant loop to convey waste heat from the electronics board to the sealed refrigerant loop.
